(19) United States
(12) Patent Application Publication
(10) Pub. No.: US 2017/0125401 A1
(43) Pub. Date: May 4, 2017

(54) BIPOLAR JUNCTION TRANSISTOR AND METHOD OF MANUFACTURING THE SAME

(71) Applicant: Dongbu Hitek Co., Ltd., Seoul (KR)

(72) Inventors: Sung Mo Gu, Chungcheongbuk-do (KR); Sung Bok Ahn, Daejeon (KR)

(21) Appl. No.: 15/335,877

(22) Filed: Oct. 27, 2016

(30) Foreign Application Priority Data
Oct. 30, 2015 (KR) 10-2015-0152453

(51) Int. Cl. H01L 27/06; H01L 21/8249; H01L 29/66; H01L 21/266; H01L 29/36; H01L 29/732

(52) U.S. Cl. CPC H01L 27/0623; H01L 29/36; H01L 29/732; H01L 29/66234; H01L 21/266; H01L 21/8249

(57) ABSTRACT

A bipolar junction transistor includes a first well region having a first conductive type, a second well region disposed adjacent to the first well region and having a second conductive type, a base disposed on the first well region and having the first conductive type, an emitter disposed on the first well region and having the second conductive type, and a collector disposed on the second well region and having the second conductive type. The first well region comprises a first impurity region and a second impurity region having an impurity concentration lower than that of the first impurity region. The base is disposed on the first impurity region, and the emitter is disposed on the second impurity region.

### CROSS-REFERENCE TO RELATED APPLICATION

This application claims the priority benefit of Korean Patent Application No. 10-2015-0152453, filed on Oct. 30, 2015 and all the benefits accruing therefrom under 35 U.S.C. §119, the contents of which are incorporated by reference in their entirety.

### BACKGROUND

The present disclosure relates to a bipolar junction transistor and a method of manufacturing the same, and more particularly, to a bipolar junction transistor (BJT) having an improved current gain (hfe) and a method of manufacturing the same.

A bipolar junction transistor has a lower noise level than an MOSFET (Metal Oxide Semiconductor Field Effect Transistor). Furthermore, the bipolar junction transistor shows a wide range of linear gain and has excellent frequency response characteristics and current driving capability, and can be fabricated on the same substrate with a CMOS device for performing any desired high frequency functions.

However, when the bipolar junction transistor is fabricated on the same substrate along with the MOSFET according to conventional techniques, it is difficult to improve the current gain of the bipolar junction transistor because a well region of the bipolar junction transistor is simultaneously formed with a well region of the MOSFET.

### SUMMARY

The present disclosure provides a bipolar junction transistor having an improved current gain and a method of manufacturing the same.

In accordance with an aspect of the present invention, a bipolar junction transistor may include a first well region having a first conductive type, a second well region disposed adjacent to the first well region and having a second conductive type, a base disposed on the first well region and having the first conductive type, an emitter disposed on the first well region and having the second conductive type, and a collector disposed on the second well region and having the second conductive type. Particularly, the first well region may include a first impurity region and a second impurity region having an impurity concentration lower than that of the first impurity region, the base may be disposed on the first impurity region, and the emitter may be disposed on the second impurity region. As used throughout this disclosure and in the claims, a “conductive type” or “conductivity type” refers to a particular combination of impurity type (e.g., n-type or p-type) as well as the impurity or dopant concentration of that type.

In accordance with some exemplary embodiments, the base may circumscribe the emitter at a surface of the bipolar junction transistor. Further, the collector may circumscribe the base at the surface of the bipolar junction transistor. For example, the base may have a ring shape surrounding the emitter, and the collector may have a ring shape surrounding the base.

In accordance with some exemplary embodiments, the bipolar junction transistor may further include device isolation regions disposed among the base, the emitter and the collector.

In accordance with some exemplary embodiments, the bipolar junction transistor may further include a deep well region having the second conductive type, and the first and second well regions may be disposed on the deep well region.

In accordance with some exemplary embodiments, the bipolar junction transistor may further include a third well region disposed adjacent to the second well region and having the first conductive type, and a well tap disposed on the third well region and having the first conductive type.

In accordance with some exemplary embodiments, the first impurity region may have the same impurity concentration as that of the third well region.

In accordance with some exemplary embodiments, the third well region may have the same impurity concentration as that of a well region of a neighboring MOSFET.

In accordance with another aspect of the present invention, a bipolar junction transistor may include a first well region having a first conductive type, a second well region disposed adjacent to the first well region and having a second conductive type, a third well region disposed adjacent to the second well region and having the first conductive type, a base disposed on the first well region and having the first conductive type, an emitter disposed on the first well region and having the second conductive type, a collector disposed on the second well region and having the second conductive type, and a well tap disposed on the third well region and having the first conductive type. Particularly, the first well region may have an impurity concentration lower than that of the third well region.

In accordance with still another aspect of the present invention, a method of manufacturing a bipolar junction transistor may include forming a first well region having a first conductive type on a substrate, forming a second well region having a second conductive type on the substrate, forming a base having the first conductive type on the first well region, and forming an emitter and a collector having the second conductive type on the first and second well regions, respectively. Particularly, the first well region may include a first impurity region and a second impurity region having an impurity concentration lower than that of the first impurity region, the base may be formed on the first impurity region, and the emitter may be formed on the second impurity region.

In accordance with some exemplary embodiments, the base may circumscribe the emitter at a surface of the bipolar junction transistor. Further, the collector may circumscribe the base at the surface of the bipolar junction transistor. For example, the base may have a ring shape surrounding the emitter, and the collector may have a ring shape surrounding the base.

In accordance with some exemplary embodiments, the method may further include forming device isolation regions to electrically isolate the base, the emitter and the collector from one another.

In accordance with some exemplary embodiments, the method may further include forming a deep well region having the second conductive type in the substrate, and the first and second well regions may be formed on the deep well region.

In accordance with some exemplary embodiments, the first impurity region may be an impurity-implanted region formed by an ion implantation process, and the second impurity region may be an un-implanted region.

In accordance with some exemplary embodiments, the method may further include forming an epitaxial layer having the first conductive type on the substrate, and the first and second well regions may be formed in surface portions of the epitaxial layer.

In accordance with some exemplary embodiments, the substrate may have the first conductive type, and the first and second well regions may be formed in surface portions of the substrate.

In accordance with some exemplary embodiments, the forming of the first well region may include forming an ion implantation mask exposing the first impurity region, and performing an ion implantation process to implant impurities into the first impurity region.

In accordance with some exemplary embodiments, the forming of the first well region may further include diffusing the impurities implanted into the first impurity region into the second impurity region.

In accordance with some exemplary embodiments, the method may further include forming a third well region having the first conductive type on the substrate, and forming a well tab having the first conductive type on the third well region. Here, the third well region may be simultaneously formed with the first well region, and the well tab may be simultaneously formed with the base.

In accordance with some exemplary embodiments, the third well region may be simultaneously formed with a well region of a neighboring MOSFET.

In accordance with some exemplary embodiments, the method may further include forming a third well region having the first conductive type on the substrate, and forming a well tab having the first conductive type on the third well region. Particularly, the first well region may have an impurity concentration lower than that of the third well region.

The above summary is not intended to describe each illustrated embodiment or every implementation of the subject matter hereof. The figures and the detailed description that follow more particularly exemplify various embodiments.

### BRIEF DESCRIPTION OF THE DRAWINGS

Exemplary embodiments can be understood in more detail from the following description taken in conjunction with the accompanying drawings, in which:

FIG. 1 is a cross-sectional view illustrating a bipolar junction transistor (BJT) in accordance with an exemplary embodiment of the present invention;

FIG. 2 is a plan view illustrating a base, an emitter and a collector as shown in FIG. 1;

FIG. 3 is a cross-sectional view illustrating a MOSFET neighboring to the bipolar junction transistor as shown in FIG. 1;

FIG. 4 is a cross-sectional view illustrating a bipolar junction transistor in accordance with another exemplary embodiment of the present invention; and

FIGS. 5 to 9 are cross-sectional views illustrating a method of manufacturing the bipolar junction transistor as shown in FIG. 1.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION OF THE DRAWINGS

Hereinafter, specific embodiments will be described in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

It will also be understood that when a layer, a film, a region or a plate is referred to as being ‘on’ another one, it can be directly on the other one, or one or more intervening layers, films, regions or plates may also be present. Unlike this, it will also be understood that when a layer, a film, a region or a plate is referred to as being ‘directly on’ another one, it is directly on the other one, and one or more intervening layers, films, regions or plates do not exist. Also, though terms like a first, a second, and a third are used to describe various components, compositions, regions and layers in various embodiments of the present invention are not limited to these terms.

In the following description, the technical terms are used only for explaining specific embodiments while not limiting the present invention. Unless otherwise defined herein, all the terms used herein, which include technical or scientific terms, may have the same meaning that is generally understood by those skilled in the art. In general, the terms defined in the dictionary should be considered to have the same meaning as the contextual meaning of the related art, and, unless clearly defined herein, should not be understood as abnormally or excessively formal meaning.

The embodiments of the present invention are described with reference to schematic diagrams of ideal embodiments of the present invention. Accordingly, changes in the shapes of the diagrams, for example, changes in manufacturing techniques and/or allowable errors, are sufficiently expected. Accordingly, embodiments of the present invention are not described as being limited to specific shapes of areas described with diagrams and include deviations in the shapes and also the areas described with drawings are entirely schematic and their shapes do not represent accurate shapes and also do not limit the scope of the present invention.

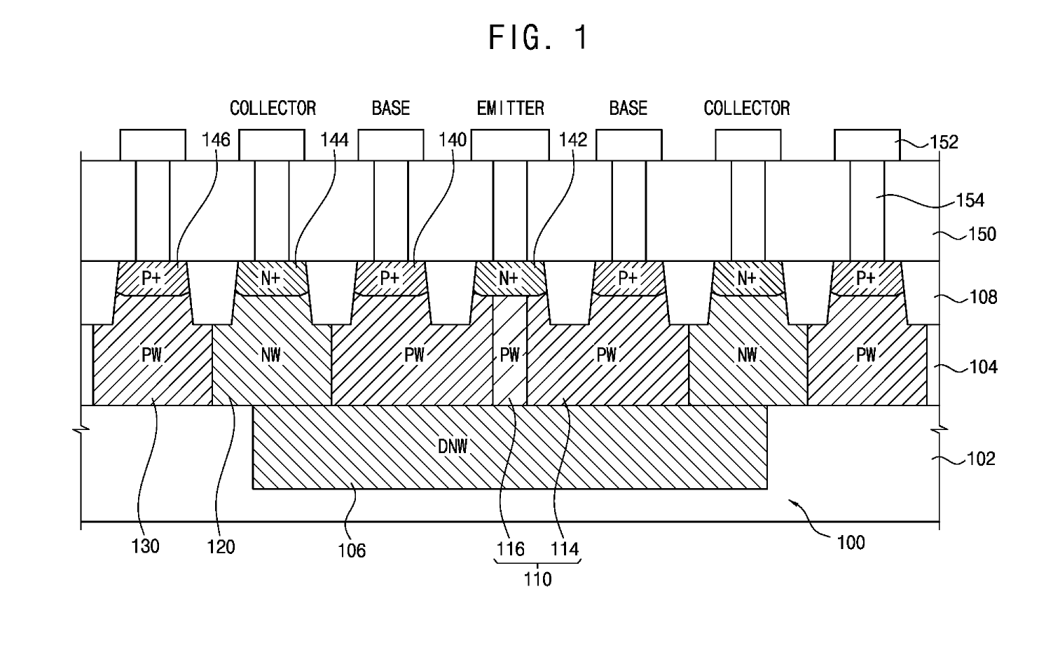

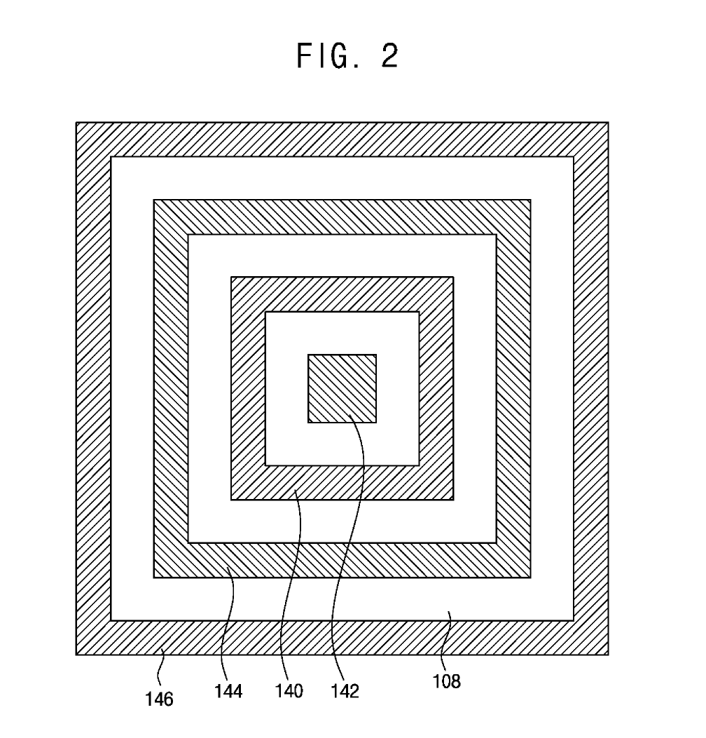

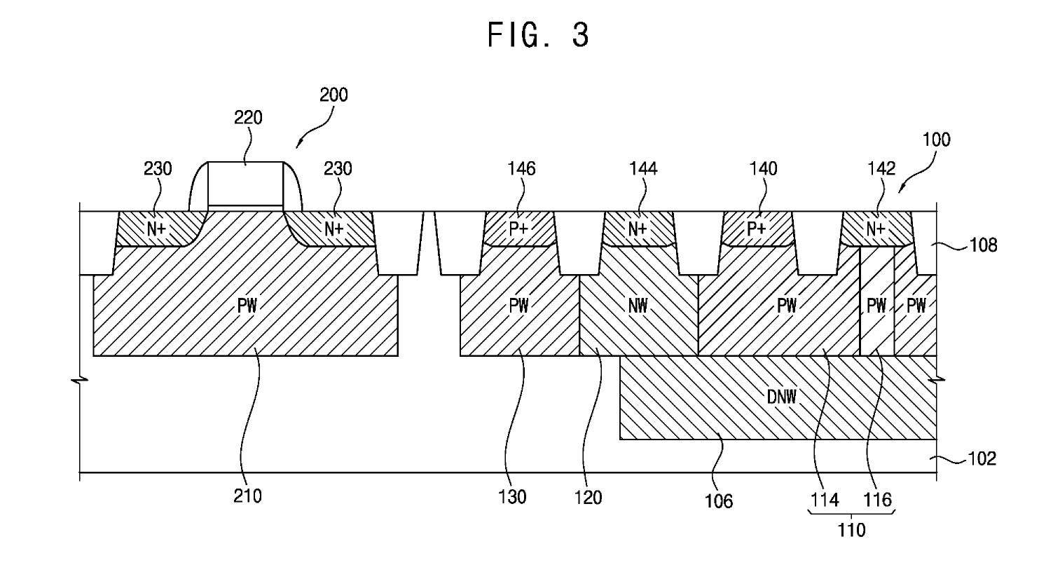

FIG. 1 is a cross-sectional view illustrating a bipolar junction transistor (BJT) in accordance with an exemplary embodiment of the present invention. FIG. 2 is a plan view illustrating a base, an emitter and a collector as shown in FIG. 1, and FIG. 3 is a cross-sectional view illustrating a MOSFET neighboring to the bipolar junction transistor as shown in FIG. 1.

Referring to FIGS. 1 to 3, a bipolar junction transistor 100, in accordance with an exemplary embodiment of the present invention, may be formed on a substrate 102 along with a MOSFET 200.

The substrate 102 may have a first conductive type. For example, a p-type substrate may be used as the substrate 102. Alternatively, a p-type epitaxial layer 104 may be formed on the substrate 102 by an epitaxial process.

The bipolar junction transistor 100 may include a first well region 110 disposed in the substrate 102 and having a first conductive type, and a second well region 120 disposed adjacent to the first well region 110 and having a second conductive type. For example, a p-type well (PW) region serving as the first well region 110 and an n-type well (NW) region serving as the second well region 120 may be formed in the substrate 102.

For clarity, FIG. 1 has been labeled with hatching corresponding to the type of impurity. As shown in FIG. 1, each p-type region arranged on substrate 102 is depicted with hatching that slants up and to the right. In contrast, each n-type region is depicted with hatching the slants up and to the left. It will be understood by one of ordinary skill in the art that these hatchings could be reversed. In other words, hatching that slants up and to the left could correspond to n-type conductivity type, whereas hatching that slants up and to the right could correspond to p-type conductivity. Spacing between hatching lines, as used in FIG. 1, denotes various levels of dopant/conductivity. Again, in alternative embodiments, the various levels of conductivity could vary from that depicted and described with respect to FIG. 1, in alternative embodiments.

As shown in FIG. 1, a base 140 having the first conductive type and an emitter 142 having the second conductive type may be disposed on the first well region 110. For example, a high concentration p-type impurity region serving as the base 140 and a high concentration n-type impurity region serving as the emitter 142 may be formed on the PW region.

A collector 144 having the second conductive type may be disposed on the second well region 120. For example, a high concentration n-type impurity region serving as the collector 144 may be formed on the NW region.

In accordance with an exemplary embodiment of the present invention, the bipolar junction transistor 100 may include a deep well region 106 having the second conductive type disposed in the substrate 102, and the first and second well regions 110 and 120 may be disposed on the deep well region 106. For example, a deep n-type well (DNW) region serving as the deep well region 106 may be formed in the substrate 102, and the first and second well regions 110 and 120 may be formed on the DNW region. As a result, two PN junctions may be formed among the emitter 142, the first well region 110 and the deep well region 106. At this time, the first well region 110 may serve as a base region, and the deep well region 106 and the second well region 120 may serve as a collector region.

Further, a third well region 130 may be disposed adjacent to the second well region 120, and a well tap 146 may be disposed on the third well region 130. For example, a second p-type well (PW) region serving as the third well region 130 may be formed on side surfaces of the second well region 120, and a second high concentration p-type impurity region serving as the well tap 146 may be formed on the second PW region. The well tap 146 and the third well region 130 may be used to apply a bias voltage to the substrate 102.

In accordance with an exemplary embodiment of the present invention, the second well region 120 may have a ring shape surrounding the first well region 110, and the third well region 130 may have a ring shape surrounding the second well region 120. Particularly, the base 140 may have a ring shape surrounding the emitter 142, and the collector 144 may have a ring shape surrounding the base 140, as shown in FIG. 2. Further, the well tap 146 may have a ring shape surrounding the collector 146, and device isolation regions 108 may be each disposed among the emitter 142, the base 140, the collector 144 and the well tap 146.

FIG. 2 shows a ring-shaped bipolar junction transistor in which emitter 142 is surrounded by square-shaped base, collector, and well tap structures. In alternative embodiments, these structures need not all be square shaped. For example, in embodiments, each of these regions can be circular. In some embodiments, base, collector, and well tap structures can have some shape anisotropy (i.e., they can be rectangular or ellipsoid). In still further embodiments, base, collector, and well tap structures need not all be the same type of shape, and the distances between them need not be identical. One of ordinary skill in the art will understand that the geometries chosen for these structures, and the spacings therebetween, can be used to affect the electrical properties of the bipolar junction transistor.

In accordance with an exemplary embodiment of the present invention, a MOSFET 200 may be disposed near the bipolar junction transistor 100, as shown in FIG. 3. The MOSFET 200 may include a well region 210 having the first conductive type, a gate electrode 220 disposed on the well region 210, and source/drain regions 230 disposed on both sides of the gate electrode 220 and having the second conductive type.

Meanwhile, the current gain (hfe) of the bipolar junction transistor 100 may be improved by reducing the impurity concentration of the base region, i.e., the first well region 110. In accordance with an exemplary embodiment of the present invention, the first well region 110 may include a first impurity region 114 and a second impurity region 116 having an impurity concentration lower than that of the first impurity region 114. At this time, the base 140 may be disposed on the first impurity region 114, and the emitter 142 may be disposed on the second impurity region 116.

Particularly, the first impurity region 114 may have the same impurity concentration as that of the third well region 130, and the third well region 130 may have the same impurity concentration as that of the well region 210 of the MOSFET 200. For example, the first impurity region 114, the third well region 130 and the well region 210 of the MOSFET 200 may be simultaneously formed by an ion implantation process. At that time, the second impurity region 116 may be an un-implanted region. That is, the second impurity region 116 may be a portion of the p-type substrate or the p-type epitaxial layer 104.

As described above, though the bipolar junction transistor 100 is formed on the same substrate 102 along with the MOSFET 200, the first well region 110 may have an impurity concentration lower than the well region 210 of the MOSFET 200, thereby improving the current gain of the bipolar junction transistor 100.

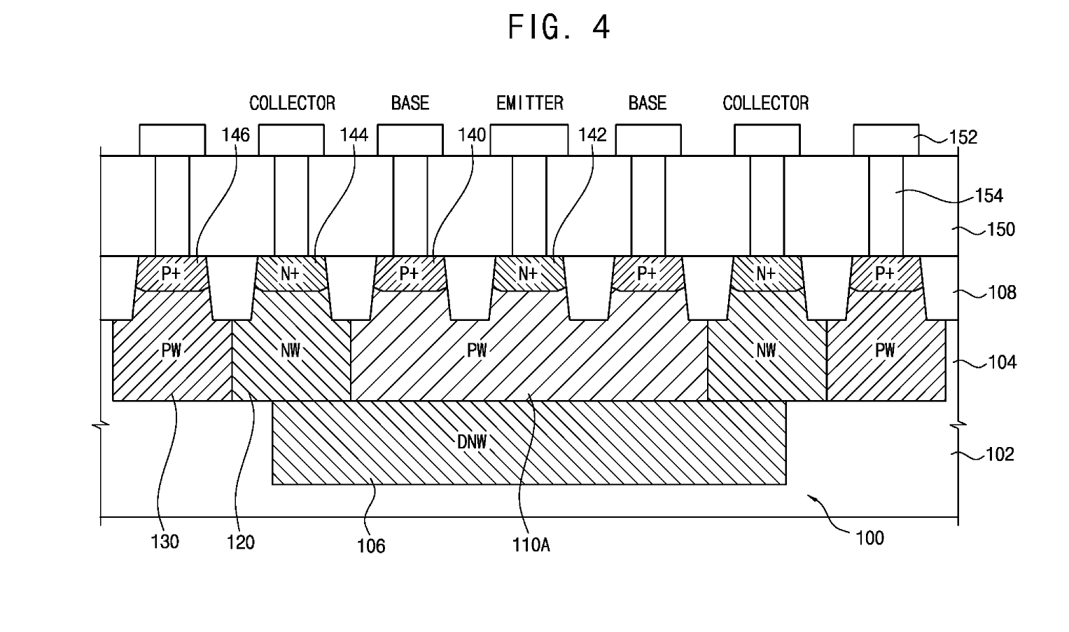

Meanwhile, after forming the first impurity region 114, a metal silicidation process, an insulating layer deposition process, and/or a metal wiring process, among other post-deposition steps, may be performed in various embodiments, and a portion of the impurities implanted into the first impurity region 114 may be diffused into the second impurity region 116, as described in more detail below with respect to FIG. 4 et seq.

FIG. 4 is a cross-sectional view illustrating a bipolar junction transistor in accordance with another exemplary embodiment.

After performing the ion implantation process for forming the first impurity region 114, a heat treatment process may be additionally performed to diffuse the impurities in the first impurity region 114 into the second impurity region 116. As a result, a first well region 110A having a uniform impurity concentration may be obtained, as shown in FIG. 4. In such case, the impurity concentration of the first well region 110A may be lower than that of the third well region 130, and thus the bipolar junction transistor 100 may have a relatively high current gain.

Meanwhile, an insulating layer 150 and a metal wiring layer 152 may be formed on the bipolar junction transistor 100, and the metal wiring layer 152 may be connected with the bipolar junction transistor 100 by contact plugs 154.

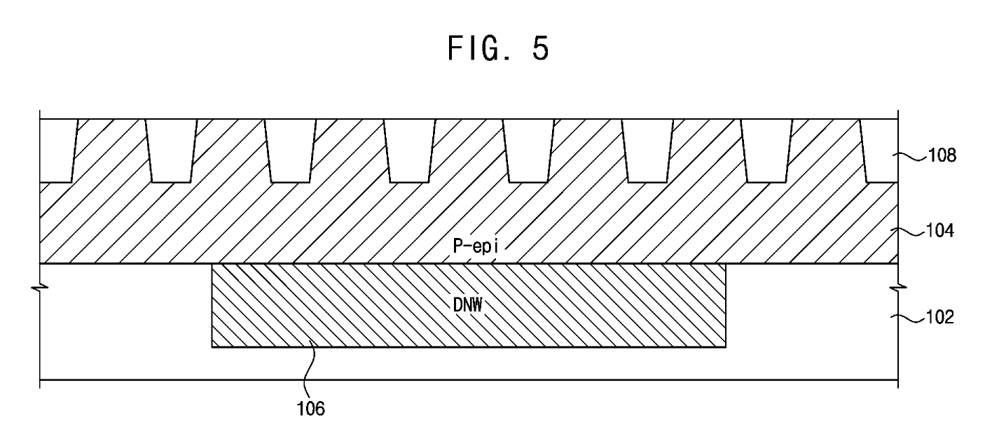

FIGS. 5 to 9 are cross-sectional views illustrating a method of manufacturing the bipolar junction transistor as shown in FIG. 1.

Referring to FIG. 5, an epitaxial layer 104 having a first conductive type, for example, a p-type epitaxial layer 104 may be formed on a substrate 102 by an epitaxial process. Alternatively, a p-type substrate may be used as the substrate 102. In such case, the epitaxial process may be omitted. Then, a deep well region 106, for example, a DNW region may be formed in the substrate 102 by an ion implantation process.

Further, device isolation regions 108 may be formed in surface portions of the epitaxial layer 104. The device isolation regions 108 may be used to electrically isolate an emitter 142 (see FIG. 1), a base 140 (see FIG. 1), a collector 144 (see FIG. 1) and a well tab 146 (see FIG. 1) with one another, or other components as will be recognized by one of skill in the art. At this time, the device isolation regions 108 may each have a ring shape, as shown for example with respect to FIG. 2.

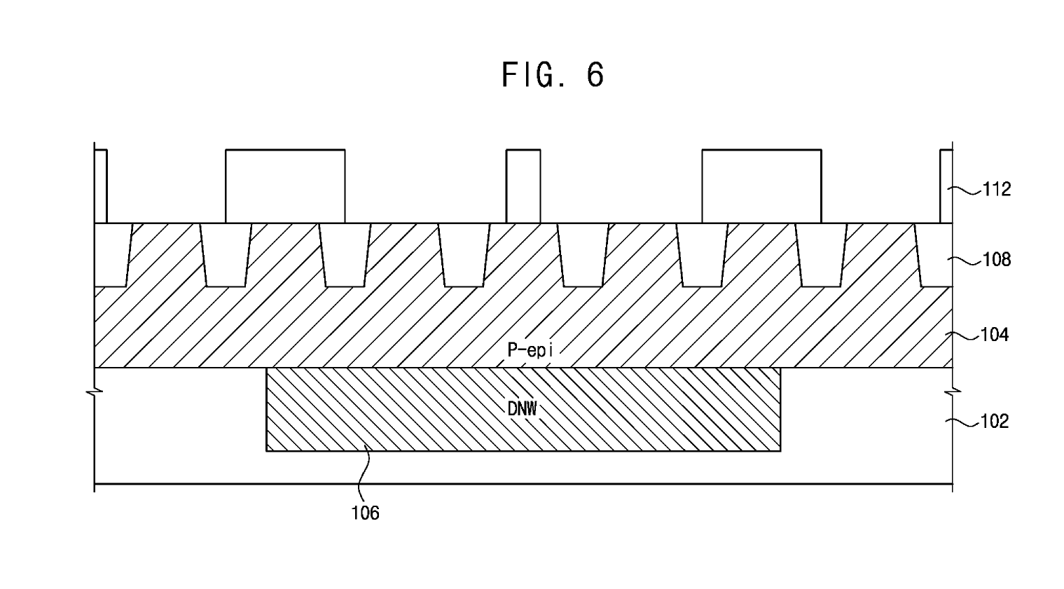

Referring to FIG. 6, a first ion implantation mask 112 for forming a first well region 110 in the epitaxial layer 104 may be formed on the epitaxial layer 104. For example, the first ion implantation mask 112 may be a photoresist pattern formed by a photolithography process.

In accordance with an exemplary embodiment of the present invention, the first ion implantation mask 112 may expose the first well region 110 except a portion of a region in which the emitter 142 will be formed. That is, the first ion implantation mask 112 may expose a first impurity region 114 and cover a second impurity region 116, as shown in FIG. 1. Further, the first ion implantation mask 112 may expose a third well region 130 and an active region of a neighboring MOSFET 200.

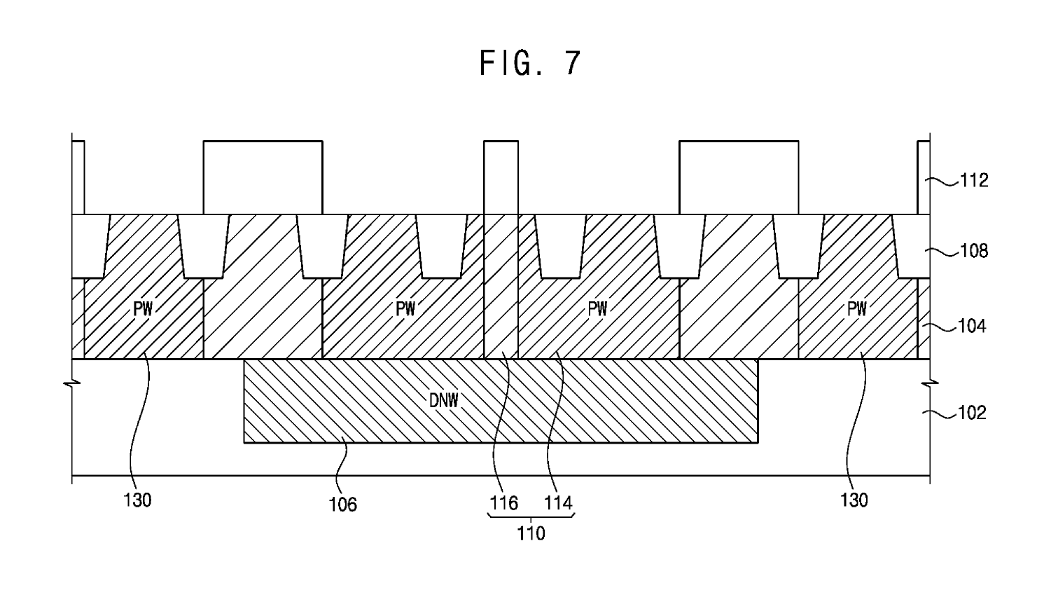

Referring to FIG. 7, an ion implantation process using the first ion implantation mask 112 may be performed, thereby forming the first well region 110 having the first conductive type, for example, a PW region in the epitaxial layer 104. The first well region 110 may be disposed on the deep well region 106 and may include a first impurity region 114 and a second impurity region 116. Particularly, the first impurity region 114 may be an impurity-implanted region, and the second impurity region 116 may be an un-implanted region.

Further, a third well region 130 having the first conductive type, for example, a second PW region may be formed by the ion implantation process. Particularly, a well region 210 of the MOSFET 200 may be simultaneously formed with the first and third well regions 110 and 130 by the ion implantation process using the first ion implantation mask 112.

After forming the first and third well regions 110 and 130, the first ion implantation mask 112 may be removed by ashing and/or strip processes, for example, or any other such method known to those of skill in the art.

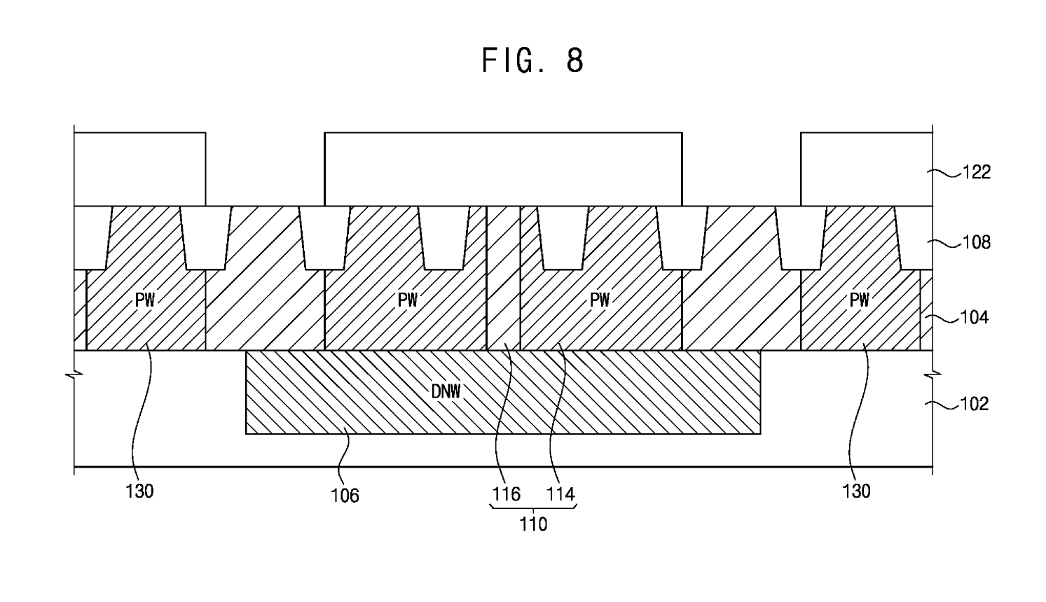

Referring to FIG. 8, a second ion implantation mask 122 for forming a second well region 120 in the epitaxial layer 104 may be formed on the epitaxial layer 104. For example, the second ion implantation mask 122 may be a photoresist pattern formed by a photolithography process, and may expose a region in which the second well region 120 will be formed.

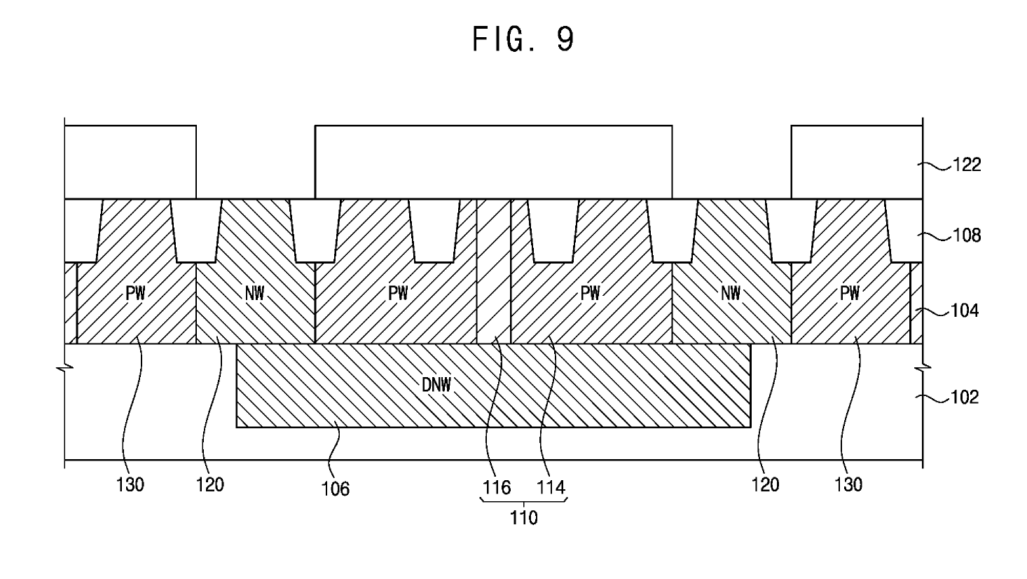

Referring to FIG. 9, an ion implantation process using the second ion implantation mask 122 may be performed, thereby forming the second well region 120 having a second conductive type, for example, an NW region in the epitaxial layer 104. At this time, the second well region 120 may be disposed on the deep well region 106.

After forming the second well region 120, the second ion implantation mask 122 may be removed by ashing and/or strip processes, for example, or any other such method known to those of skill in the art.

Meanwhile, when the p-type substrate is used as the substrate 102, the first, second and third well regions 110, 120 and 130 may be formed in surface portions of the p-type substrate.

Then, as shown in FIG. 1, a base 140 having the first conductive type may be formed on the first impurity region 114 of the first well region 110. Further, an emitter 142 having the second conductive type may be formed on a central portion of the first well region 110, i.e., on the second impurity region 116, and a collector 144 having the second conductive type may be formed on the second well region 120.

For example, a high concentration p-type impurity region serving as the base 140 may be formed on the first impurity region 114, and high concentration n-type impurity regions serving as the emitter 142 and the collector 144 may be formed on the second impurity region 116 and the second well region 120, respectively. Further, a high concentration p-type impurity region serving as the well tab 146 may be formed on the third well region 130 along with the base 140.

The base 140, the emitter 142 and the collector 144 may be formed by ion implantation processes, in an embodiment. Particularly, in such embodiments, the source/drain regions 230 of the MOSFET 200 may be simultaneously formed with the emitter 142 and the collector 144.

Meanwhile, a portion of the impurities implanted into the first impurity region 114 may be diffused into the second impurity region 116 while subsequently performing a metal silicidation process, an insulating layer deposition process, a metal wiring process, etc., as previously described with respect to FIG. 4.

Alternatively, a heat treatment process may be additionally performed to diffuse impurities in the first impurity region 114 into the second impurity region 116, thereby forming a first well region 110A having a uniform impurity concentration, as shown in FIG. 4.

In accordance with exemplary embodiments of the present invention as described above, when the bipolar junction transistor 100 and the MOSFET 200 are formed on the same substrate 102, the first well region 110 of the bipolar junction transistor 100 may be simultaneously formed with the well region 210 of the MOSFET 200. At this time, the first well region 110 may include an impurity-implanted region (the first impurity region 114) and an un-implanted region (the second impurity region 116), and the base 140 and the emitter 142 may be formed on the impurity-implanted region and the un-implanted region, respectively.

Particularly, the first well region 110 may serve as a base region of the bipolar junction transistor 100, and may have a relatively low impurity concentration in comparison with the well region 210 of the MOSFET 200. Thus, the bipolar junction transistor 100 may be simultaneously formed on the same substrate 102 with the MOSFET 200, and the current gain of the bipolar junction transistor 100 may be improved as well.

Although the bipolar junction transistor 100 and the method of manufacturing the same have been described with reference to the exemplary embodiments, they are not limited thereto. Therefore, it will be readily understood by those skilled in the art that various modifications and changes can be made thereto without departing from the spirit and scope of the present invention defined by the appended claims.

Various embodiments of systems, devices, and methods have been described herein. These embodiments are given only by way of example and are not intended to limit the scope of the claimed inventions. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the claimed inventions.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35 U.S.C. §112(f) are not to be invoked unless the specific terms “means for” or “step for” are recited in a claim.

1. A bipolar junction transistor comprising:
a first well region having a first conductive type;
a second well region disposed adjacent to the first well region and having a second conductive type;
a base disposed on the first well region and having the first conductive type;
an emitter disposed on the first well region and having the second conductive type; and
a collector disposed on the second well region and having the second conductive type,
wherein the first well region comprises a first impurity region, an impurity concentration of the second impurity region is lower than an impurity concentration of the first impurity region, the base is disposed on the first impurity region, and the emitter is disposed on the second impurity region.

2. The bipolar junction transistor of claim 1, wherein the base circumscribes the emitter at a surface of the bipolar junction transistor.

3. The bipolar junction transistor of claim 1, further comprising device isolation regions disposed among the base, the emitter and the collector.

4. The bipolar junction transistor of claim 1, further comprising a deep well region having the second conductive type,
wherein the first and second well regions are disposed on the deep well region.

5. The bipolar junction transistor of claim 1, further comprising:
a third well region disposed adjacent to the second well region and having an impurity concentration of the first conductive type; and
a well tap disposed on the third well region and having the first conductive type.

6. The bipolar junction transistor of claim 5, wherein the impurity concentration of the first impurity region is approximately equal to the impurity concentration of the third well region.

7. The bipolar junction transistor of claim 5, wherein the impurity concentration of the third well region is approximately the same as an impurity concentration of a well region of a neighboring MOSFET.

8. A bipolar junction transistor comprising:
a first well region having a first conductive type;
a second well region disposed adjacent to the first well region and having a second conductive type;
a third well region disposed adjacent to the second well region and having the first conductive type;
a base disposed on the first well region and having the first conductive type;
an emitter disposed on the first well region and having the second conductive type;
a collector disposed on the second well region and having the second conductive type; and
a well tap disposed on the third well region and having the first conductive type,
wherein the first well region has an impurity concentration lower than that of the third well region.

9. A method of manufacturing a bipolar junction transistor comprising:
forming a first well region having a first conductive type on a substrate;
forming a second well region having a second conductive type on the substrate;
forming a base having the first conductive type on the first well region;
forming an emitter having the second conductive type on the first well region; and
forming a collector having the second conductive type on the second well region;
wherein the first well region comprises a first impurity region and a second impurity region, the second impurity region having an impurity concentration lower than an impurity concentration of the first impurity region, wherein the base is formed on the first impurity region, and wherein the emitter is formed on the second impurity region.

10. The method of claim 9, wherein the base circumscribes the emitter at a surface of the bipolar junction transistor.

11. The method of claim 9, further comprising forming device isolation regions to electrically isolate the base, the emitter and the collector from one another along a surface of the bipolar junction transistor.

12. The method of claim 9, further comprising forming a deep well region having the second conductive type in the substrate, wherein the first and second well regions are formed on the deep well region.

13. The method of claim 9, wherein the first impurity region is an impurity-implanted region formed by an ion implantation process, and the second impurity region is an un-implanted region.

14. The method of claim 9, further comprising forming an epitaxial layer having the first conductive type on the substrate, wherein the first and second well regions are formed on surface portions of the epitaxial layer.

15. The method of claim 9, wherein the substrate has the first conductive type, and the first and second well regions are formed on surface portions of the substrate.

16. The method of claim 9, wherein the forming the first well region comprises:
forming an ion implantation mask exposing the first impurity region; and
performing an ion implantation process to implant impurities into the first impurity region.

17. The method of claim 16, wherein the forming the first well region further comprises diffusing the impurities implanted into the first impurity region into the second impurity region.

18. The method of claim 9, further comprising:
forming a third well region having the first conductive type on the substrate; and
forming a well tab having the first conductive type on the third well region,
wherein the third well region is simultaneously formed with the first well region, and the well tab is simultaneously formed with the base.

19. The method of claim 18, wherein the third well region is simultaneously formed with a well region of a neighboring MOSFET.

20. The method of claim 9, further comprising:
forming a third well region having the first conductive type on the substrate; and
forming a well tab having the first conductive type on the third well regions,
wherein the first well region has an impurity concentration lower than that of the third well region.
